(19) United States
(12) Patent Application Publication
(10) Pub. No.: US 2002/0076905 A1
(43) Pub. Date: Jun. 20, 2002

(54) Method of eliminating silicon residual from wafer after dicing saw process

(76) Inventors: Yuan-Fu Lin, Da-Li City (TW); Yueh-Liang Chen, Feng-Yuan City (TW)

Correspondence Address: BACON & THOMAS, 4th Floor, 625 Slaters Lane, Alexandria, VA, 22314, US

(21) Appl. No.: 09/736,287

(22) Filed: Dec. 15, 2000

(51) Int. Cl. H01L 21/301

(52) U.S. Cl. 438/465

(57) ABSTRACT

Method of eliminating silicon residual from wafer after dicing saw process includes the steps of adhering a first adhesive tape or coating a cover layer on the surface of a wafer, transferring the adhered or coated wafer to a wafer dicing machine for forming dies, and removing the first adhesive tape or cover layer from the wafer. Silicon residual generated during dicing saw process will be deposited on the first adhesive tape or cover layer without depositing on the die surface. Removing the adhesive tape or cover layer will also remove the silicon residual. Thus wafer surface may be prevented from contamination of silicon residual and the consequent manufacturing processes and product quality won't be adversely affected.

### BACKGROUND OF THE INVENTION

This invention relates to a method of eliminating silicon residual from wafer after dicing saw process and particularly a method that adhering an adhesive tape or coating a cover layer on the surface of a wafer before dicing saw process for preventing silicon residual generated during the dicing saw process from depositing on the die surface.

In semiconductor manufacturing process, a plurality of rectangular dies are formed concurrently on a piece of wafer. Each die has the size about 5 to 10 millimeters and contains up to million of electric circuit elements. The wafer will be transferred to a dicing saw process to form individual dies. Each die then will be soldered to a circuit board, and be packaged for use. The purpose of the dicing saw process is to cut the finished wafer into dies according to a preset street formed on the wafer surface. Conventionally (as shown in FIG. 1), a step of wafer mount process 4 will be proceeded before performing dicing saw process. This step includes mounting the rear side of the wafer on a hollow section of a steel frame, and adhering a wafer tape to the rear side of the wafer and the steel frame. The wafer then will be transferred to a wafer dicing machine (not shown in the figure) for dicing saw process. After the dicing saw process is completed, the dies will be laid neatly on the surface of the wafer tape and adhere to thereof. The support of the steel frame may prevent the wafer tape from crumpling so that the dies won't bump against one another. The frame also holds the wafer tape to facilitate transportation and subsequent processes.

The wafer is made from high purity silicon. During dicing saw process, certain amount of silicon residual will be generated no matter what kind of cutting tools are used. In order to maintain product quality, super pure D.I. water will be used to clean the cutting tools for washing away the silicon residual generated during the dicing saw process. Furthermore, carbon dioxide (CO2) usually will be added in the water for removing electrostatic charge that might result from the cutting operation. However, too much carbon dioxide might produce excessive carbonic hydrogen ions (HCO3) and make water become acid. The acid water will erode die surface and damage the dies. Moreover, during cleaning process, if water ejection angle is not proper or water pressure not sufficient, the cleaning will be not effective and may result in formation of silicon residual. On the other hand, if water pressure is too high, wafer surface may suffer from undue stress and get damaged. Hence water pressure must be controlled properly all the time to avoid aforesaid problems. If silicon residual were generated, a lot of quality problems will ensue in the subsequent manufacturing processes, such as shear strength of the bonding joint between Au wire and the die will be impaired during wire bonding process, or aforesaid defective bonding joint of Au wire might break away when subject to impact of resin flow in the package molding, or contamination of silicon residual might weaken the adhesive force between the package resin and die surface and cause delamination at the adhering spot.

### SUMMARY OF THE INVENTION

In view of aforesaid disadvantages, it is therefore an object of this invention to provide an improved method for effectively preventing silicon residual from depositing on the die surface during dicing saw process.

It is another object of this invention to provide a method that offers a shield interface during cleaning the dies with D.I. water in the wafer dicing saw process for preventing die surface from direct contact with D.I water so that damage caused by stress may be avoided.

It is a further object of this invention to provide a protective layer over the die surface for preventing carbon dioxide (CO2) water from directly eroding die surface during cleaning process to ensure that subsequent manufacturing processes and product quality won't be adversely affected.

In order to achieve aforesaid objects, initially adhering a first transparent adhesive tape or coating a transparent cover layer on the surface of a wafer in the method of this invention. The wafer then is transferred to a wafer dicing machine for dicing saw process. After the dicing saw process has been completed and dies are formed, the first adhesive tape or cover layer is removed from the dies. Hence the first adhesive tape or cover layer may prevent silicon residual generated during the dicing saw process from depositing on the surface of the dies. When the first adhesive tape or cover layer is removed, the silicon residual deposited on the first adhesive tape or cover layer will also be removed.

### BRIEF DESCRIPTION OF THE DRAWINGS

The invention, as well as its many advantages, may be further understood by the following detailed description and drawings, in which:

FIG. 1 is a flow chart of a conventional wafer dicing saw process.

FIG. 2 is a flow chart of wafer dicing saw process of this invention.

FIG. 3 is flow chart of another wafer dicing saw process of this invention.

FIG. 4A, 4B, 4C and 4D are pictorial views of the process steps of this invention.

FIG. 5A, SB and 5C are schematic views of the process steps of another embodiment of this invention.

### DESCRIPTION OF THE PREFERRED EMBODIMENTS

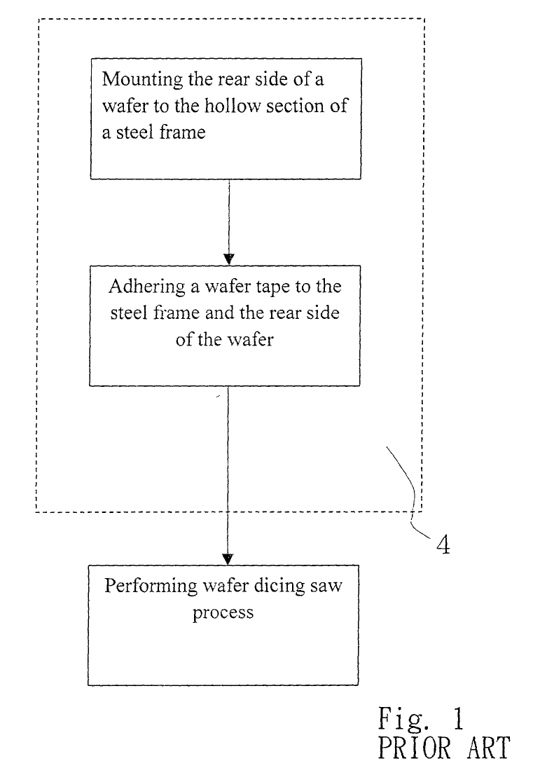

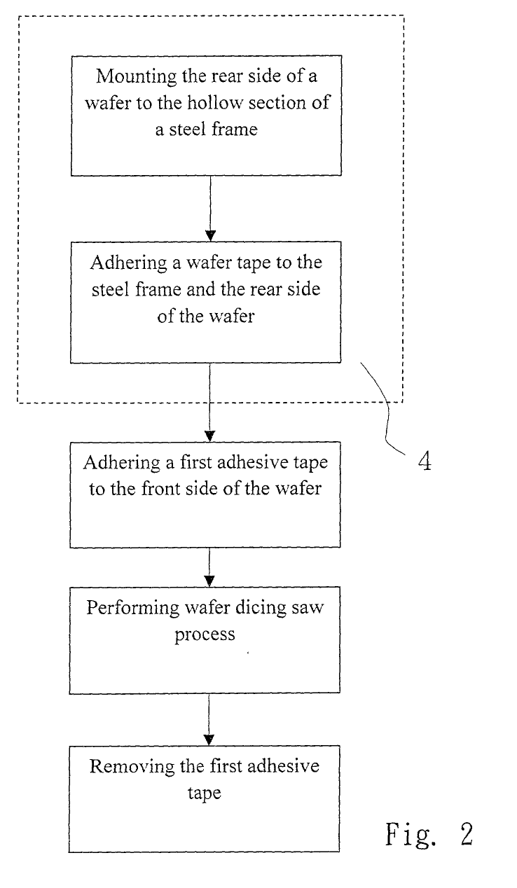

Referring to FIGS. 1 to 5. FIG. 1 shows a conventional dicing saw process flow. The initial process is wafer mount process 4 which includes mounting the rear side of the wafer 1 on a hollow section of a steel frame 3 and adhering a wafer tape 2 to the rear side of the wafer 1 and the steel frame 3. Then the wafer 1 is transferred to a wafer dicing machine (not shown in the figure) for dicing saw process to form individual dies of substantially equal size. Referring to FIG. 2, the dicing saw process according to this invention eventually adapts the wafer mount process 4 used in the conventional process set forth above. However after mounting the wafer 1 on the steel frame 3 and adhering the wafer tape 2 to the rear side of the wafer 1 and the steel frame 3, a first transparent adhesive tape 6 larger than the size of the wafer 1 will be provided to cover and adhere to the front side of the wafer 1. Then the wafer 1 is transferred to the wafer dicing machine for dicing saw process to produce individual dies. After the dicing saw process is completed, the first adhesive tape 6 will be removed. Then the dies adhered to the wafer tape 2 will be transferred to subsequent manufacturing processes desired.

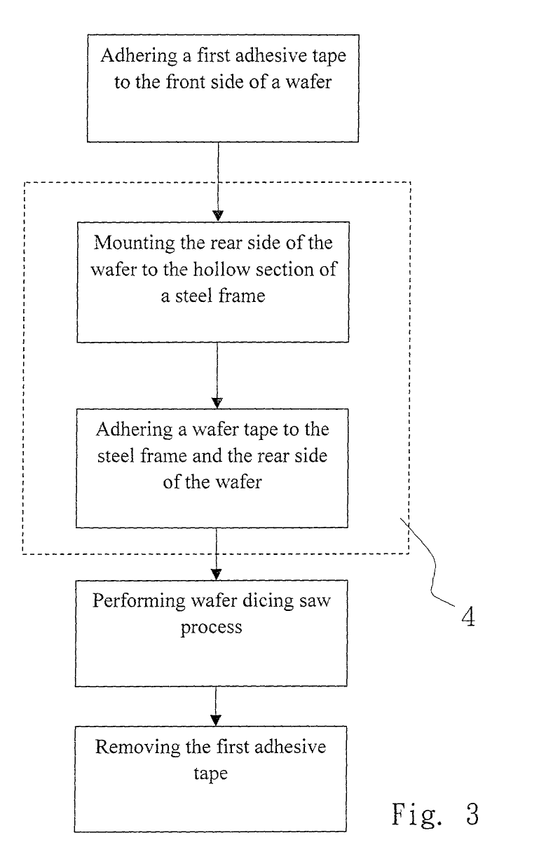

FIG. 3 shows another dicing saw process flow of this invention. It is largely like the one shown in FIG. 2. However the step of adhering the first adhesive tape 6 larger than the size of the wafer 1 to the front side of the wafer 1 is done before the process of the wafer mount process 4. After the first adhesive tape 6 has been stuck to the wafer 1, mounting the rear side of the wafer 1 on the hollow section of the steel frame 3, and adhering the rear side of the wafer 1 and the steel frame 3 to the wafer tape 2. Then the wafer 1 is transferred to the wafer dicing machine for dicing saw process. After the dicing saw process is completed, the first adhesive tape 6 will be removed. Then the dies adhered to the wafer tape 2 will be transferred to subsequent manufacturing processes desired.

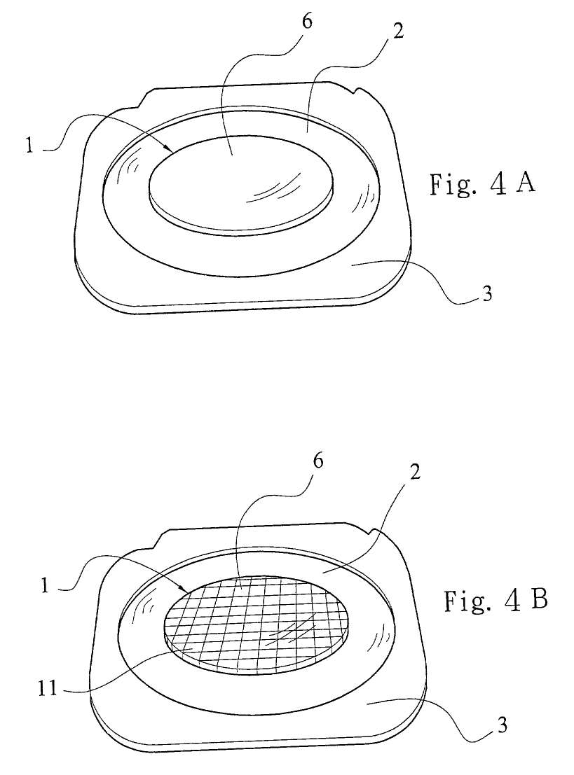

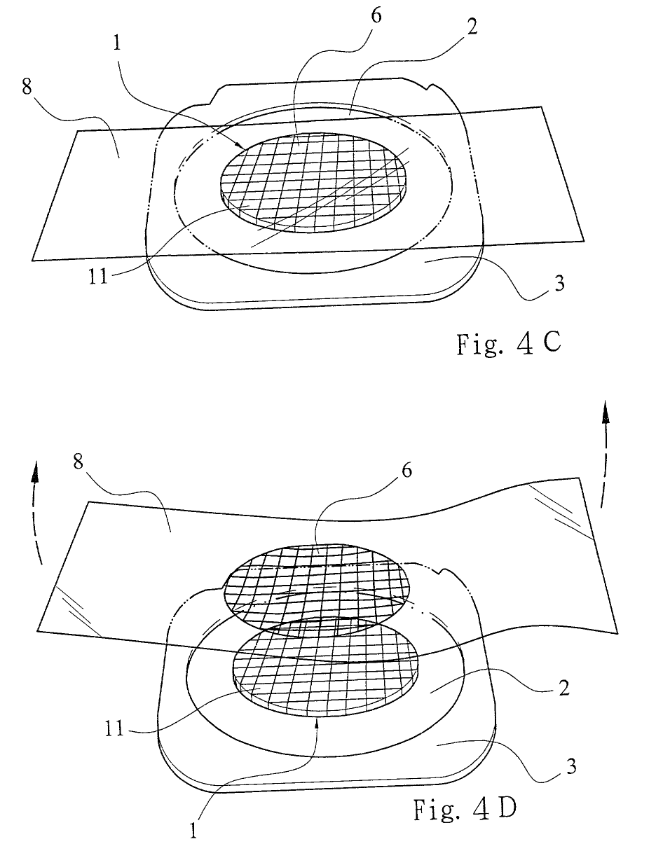

FIGS. 4A through 4D illustrate individual steps of this invention. As shown in FIG. 4A, the wafer mount process is done initially which includes mounting the rear side of the wafer 1 on a hollow section of a steel frame 3 that is larger than the size of the wafer 1, and evenly adhering the rear side of the wafer 1 and the steel frame 3 to a wafer tape 2 for positioning the wafer 1 at a selected location of the steel frame 3. Then adhere a first adhesive tape 6 to the front side of the wafer 1. The first adhesive tape 6 is made from polyimide or polyvinyl chloride (PVC) which may withstand temperature up to 400° C. The first adhesive tape 6 has adhesive force on the surface facing the wafer 1 for adhering the front surface of the wafer 1 evenly. Referring to FIG. 4B, the wafer 1 with the first adhesive tape 6 attached thereon is transferred to a wafer dicing machine (not shown in the figure) for dicing saw process to produce a plurality of individual dies 11 which are laid neatly after cutting. The dies 11 after cutting still have their front surfaces adhered to the first adhesive tape 6 and their rear sides attached to the wafer tape 2. Referring to FIG. 4C, after the cutting of the wafer 1 is completed, deploy a second adhesive tape 8 which has a larger size than the first adhesive tape 6 (and also larger than the wafer 1) to cover and adhere to the front side of the first adhesive tape 6 completely. The second adhesive tape 8 sticks to the first adhesive tape 6 with a stronger adhesive force than the adhesive force existing between the first adhesive tape 6 and wafer 1. Referring to FIG. 4D, after the second adhesive tape 8 has been stuck to the first adhesive tape 6, remove the second adhesive tape 8 away from the wafer 1. The first adhesive tape 6, stuck to the second adhesive tape 8 with a stronger adhesive force, will also be peeled away from the wafer 1.

As an embodiment alternative, in the processes set forth above, the step of adhering the first adhesive tape 6 to the front side of the wafer 1 may be proceeded before the wafer mount 4 step (also referring to FIG. 3). Then mount the rear side of the wafer 1 on a hollow section of the steel frame 3 and adhere the rear side of the wafer 1 and the steel frame 3 to the wafer tape 2. Transfer the wafer 1 to the wafer dicing machine for producing a plurality of dies 11. Thereafter, adhere the second adhesive tape 8 to the first adhesive tape 6. Finally, remove the second adhesive tape 8 to peel the first adhesive tape 6 away from the front side of the wafer 1.

During the dicing saw operation, the first adhesive tape 6 covers the front side of the wafer 1 to form a shield interface. Hence silicon residual generated during dicing saw process will be deposited on the surface of the first adhesive tape 6 without directly contacting the surface of the cutting dies 11. When the second adhesive tape 8 sticks to the first adhesive tape 6 and peels off the first adhesive tape 6 later, the silicon residual deposited on the surface of the first adhesive tape 6 will also be removed. Hence silicon residual does not contaminate the dies 11 surfaces. Furthermore, when the wafer 1 with the first adhesive tape 6 attached thereon is under the dicing saw process, the first adhesive tape 6 forms a shield interface for preventing cleaning D.I. water from direct contact with the dies 11 surfaces. As a result, the stress damage that might otherwise happen to the dies 11 surfaces resulting from exposing to D.I water may be avoided. Moreover, the first adhesive tape 6 covered the wafer 1 may shield the dies 11 surfaces from contact with the acid CO2-contained water which is being used for cleaning the surfaces of the dies 11 during dicing saw process (the cleaning process is known in the art and will be omitted herein). The dies 11 surfaces thus have a protective interface which may reduce erosion that might otherwise incur. All this may improve consequent manufacturing processes.

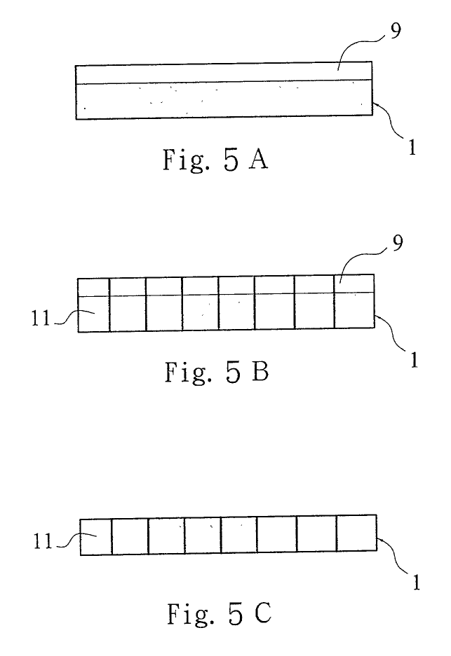

FIGS. 5A, 5B and 5C show process steps of another embodiment of this invention. Referring to FIG. 5A, the surface of the wafer 1 is coated with a transparent cover layer 9 to a selected thickness. The cover layer 9 is made from polyimide (with temperature withstanding capability about 400° C.) which is coated evenly on the wafer 1 surface. Then transfer the coated wafer 1 to dicing saw machine (not shown in the figures) for dicing saw process to form individual dies 11 (shown in FIG. 5B). Thereafter, use hot alkaline solution or hydrazine to dissolve the polyimide cover layer 9 from the dies 11 surface for completing the wafer cutting process (shown in FIG. 5C).

Because the wafer 1 front surface has the cover layer 9 attached thereon, silicon residual generated during the dicing saw process will be deposited on the cover layer 9 and may be removed by dissolving the cover layer 9 through using hot alkaline solution or hydrazine without depositing on the dies 11 surfaces. The cover layer 9 also forms a shield interface for preventing D.I. water from contact with the dies 11 surfaces during the dicing saw process. As a result, the stress damage that might otherwise happen to the dies 11 surfaces resulting from exposing to D.I water may be avoided. Moreover, the cover layer 9 covered the wafer 1 may shield the dies 11 surfaces from contact with the acid C02-contained water during dicing saw process. The dies 11 surfaces thus have a protective interface for reducing erosion that might otherwise incur. All this may improve subsequent manufacturing processes.

It may thus be seen that the objects of the present invention set forth herein, as well as those made apparent from the foregoing description, are efficiently attained. While the preferred embodiments of the invention have been set forth for purpose of disclosure, modifications of the disclosed embodiments of the invention as well as other embodiments thereof may occur to those skilled in the art. Accordingly, the appended claims are intended to cover all embodiments which do not depart from the spirit and scope of the invention.

What is claimed is:

1. A method of eliminating silicon residual from wafer after dicing saw process comprising the following steps:
a. adhering a first adhesive tape to the surface of a wafer;
b. transferring the wafer covered by the first adhesive tape to a wafer dicing machine to cut the wafer; and
c. removing the first adhesive tape from the surface of the wafer such that silicon residual generated from cutting the wafer will be removed with the first adhesive tape without depositing on the wafer surface.

2. The method according to claim 1, wherein the first adhesive tape is transparent.

3. The method according to claim 1, wherein the first adhesive tape is removed from the wafer surface by peeling.

4. The method according to claim 1, wherein the first adhesive tape has adhesive force on the side adhering to the wafer surface.

5. The method according to claim 1, wherein the first adhesive tape is selectively made from polyimide or polyvinyl chloride.

6. The method according to claim 1, wherein the first adhesive tape has adhesive force on both sides thereof.

7. The method according to claim 3, wherein the peeling of the first adhesive tape is done by means of adhering a second adhesive tape of a stronger adhesive force to the first adhesive tape then removing the second adhesive tape.

8. A method of eliminating silicon residual from wafer after dicing saw process comprising the following steps:
a. coating a cover layer on the surface of a wafer;
b. transferring the wafer coated with the cover layer to a wafer dicing machine to cut the wafer; and
c. removing the cover layer from the surface of the wafer such that silicon residual generated from cutting the wafer will be removed with the cover layer without depositing on the wafer surface.

9. The method according to claim 8, wherein the cover layer is transparent.

10. The method according to claim 8, wherein the cover layer is selectively made from polyimide.

11. The method according to claim 8, wherein the cover layer is removed by dissolution through using hot alkaline solution or Hydrazine.
